(19) United States
(12) Patent Application Publication
(10) Pub. No.: US 2013/0344443 A1
(43) Pub. Date: Dec. 26, 2013

(54) LITHOGRAPHY APPARATUS, AND METHOD OF MANUFACTURE OF PRODUCT

(71) Applicant: CANON KABUSHIKI KAISHA, Tokyo (JP)

(72) Inventors: Takayuki Kawamoto, Tokyo (JP); Kentaro Sano, Utsunomiya-shi (JP)

(21) Appl. No.: 13/925,929

(22) Filed: Jun. 25, 2013

(30) Foreign Application Priority Data
Jun. 26, 2012 (JP) 2012-142848

(51) Int. Cl. H01J 37/317

(52) U.S. Cl. CPC H01J 37/3174
USPC 430/296; 250/398

(57) ABSTRACT

A lithography apparatus writes with a charged particle beam on a substrate scanned in a first direction. The apparatus includes a shielding device which individually shields a plurality of charged particle beams in first and second charged particle beam groups, a holder for the substrate movable in the first direction, and a controller. If a defective beam that does not satisfy a condition exists in the first charged particle beam group, the controller is configured to cause the shielding device to shield the defective beam and to transmit a compensating beam, of the second charged particle beam group, for compensating for the defective beam, and to control writing with the compensating beam based on relative positions, in the first direction, between the compensating beam and a charged particle beam to be compensated for by the compensating beam.

### BACKGROUND OF THE INVENTION

1. Field of the Invention

The present disclosure relates to a lithography apparatus that performs writing on a substrate with a plurality of charged particle beams, and to a method of manufacturing an article.

2. Description of the Related Art

A lithography apparatus that executes writing on a substrate by controlling the blanking, and deflecting and scanning with a charged particle beam such as an electron beam is known. This lithography apparatus is employed as a pattern formation technique in substitution for an optical exposure method in the product or the like of a 4 GDRAM and higher memory device having a line width of no more, than 0.1 micrometers An example of this lithography apparatus is a multibeam lithography apparatus that executes writing using a plurality of charged particle beams to meet a request for higher throughput. In relation to the above type of multibeam lithography apparatus, PCT Laid Open Application 2009/147202 discloses a writing method in which sub-beams configured by further division of the plurality of charged particle beams are used separately for deflection and scanning in response to a written pattern to thereby write a striped region connected to a substrate. In this writing method, abnormal charged particle beams (including sub-beams) that prevents writing of a desired pattern on the substrate is shielded so as not to reach the substrate. At this time, blank portions are produced on the striped region that were to be written by the shielded charged particle beams. Thus, Published Japanese Translation No. 2009-503844 discloses a writing method for writing the striped region with blank, portions using a normal charged particle beam after two or more writing operations and compensating.

However, there is a possibility that the throughput is greatly reduced when the writing method disclosed in Published Japanese Translation No. 2009-503844 is performed.

### SUMMARY OF THE INVENTION

The present invention provides, for example, a lithography apparatus that compensates for a defective charged particle beam and has advantage of throughput.

According to an aspect of the present disclosure, the lithography apparatus performs writing with a charged particle beam on a substrate scanned in a first direction, and includes a shielding device configured to individually shield a plurality of charged particle beams included in a first charged particle beam group and a second charged particle beam group, a holder configured to hold the substrate and to be movable in the first direction, and a controller. The controller is configured, if a defective beam that does not satisfy a condition exists in the first charged particle beam group, to cause the shielding device to shield the detective beam and to transmit a compensating beam, of the second charged particle beam group, for compensating for the defective beam, and to control writing with the compensating beam based on relative positions, in the first direction, between the compensating beam and a charged particle beam to be compensated for by the compensating beam.

Further features of the present disclosure will become apparent from the following description of embodiment (with reference to the attached drawings).

### BRIEF DESCRIPTION OF THE DRAWINGS

FIG. 1 illustrates a configuration example of a lithography apparatus according to a first embodiment of the present disclosure.

FIGS. 2A and 2B illustrate a basic operation during writing using the lithography apparatus.

FIGS. 3A and 3B illustrate a basic operation during writing using the lithography apparatus.

FIG. 4 illustrates a state in which a normal writing region is written on a substrate.

FIG. 5 illustrates a configuration during writing compensation according to a first example of the first embodiment.

FIG. 6 illustrates a configuration during writing compensation according to a second example of the first embodiment.

FIG. 7 illustrates a configuration during writing compensation according to a third example of the first embodiment.

FIG. 8 illustrates a configuration during writing compensation according to a fourth example of the first embodiment.

FIG. 9 illustrates a configuration during writing compensation according to a fifth example of the first embodiment.

FIG. 10 illustrates a configuration during writing compensation according to a sixth example of the first embodiment.

FIG. 11 illustrates a configuration of a lithography apparatus according to a second embodiment of the present disclosure.

### DESCRIPTION OF THE EMBODIMENTS

The preferred embodiment for execution of the present disclosure will be described below with reference to the figures.

### First Embodiment

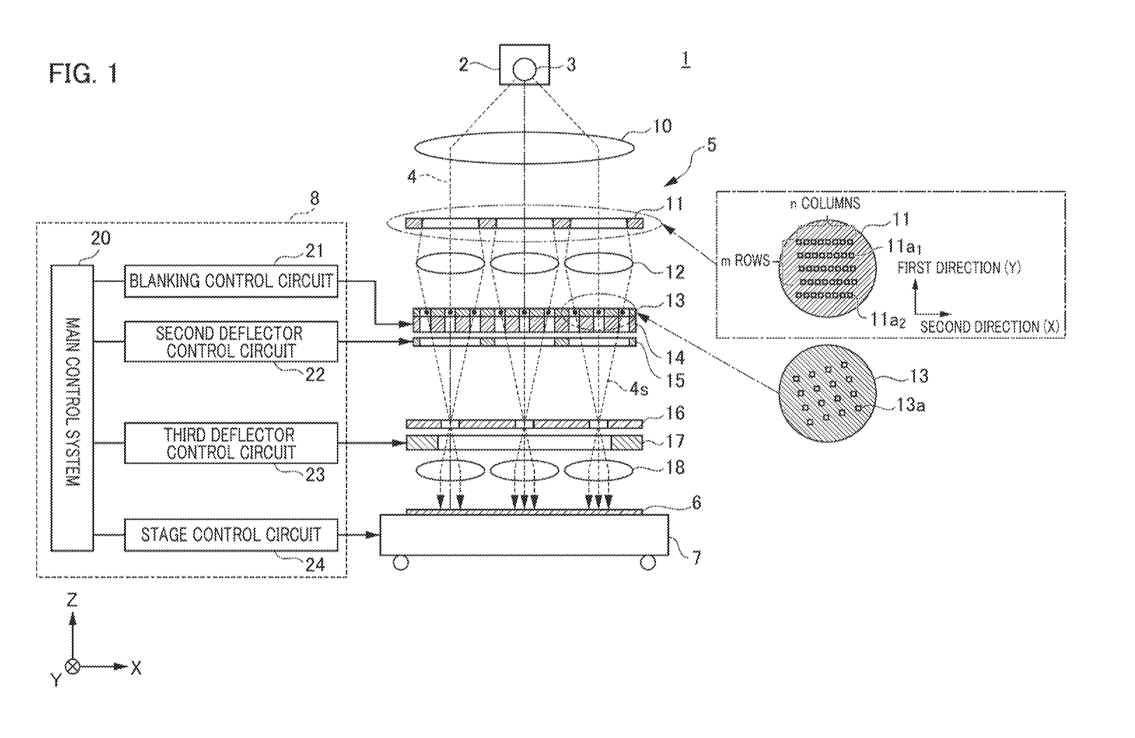

Firstly, a lithography apparatus according to a first embodiment of the present disclosure will be described. The lithography apparatus that is described in the embodiment is configured as a multibeam lithography apparatus that writes a predetermined pattern onto a predetermined position of a substrate by deflecting a plurality of charged particle beams and executing separate control of the blanking (irradiation OFF position) of the charged particle beam. As used herein, charged particle beam means an electron beam or ion beam. FIG, 1 is a schematic view of the configuration of the lithography apparatus 1 according to the present embodiment. In FIG. 1, a Z axis is configured in a nominal irradiation direction of a charged particle beam relative to the substrate, and the X axis and Y axis are orthogonally disposed in a plane that is perpendicular to the Z axis. The first direction and the second direction as used in the following description are mutually orthogonal and parallel to the surface of the substrate. The first direction is the direction in which the substrate is moved by the substrate stage (stage moving direction). In particular, in the present embodiment, the first direction corresponds to the Y axis direction, and the second direction corresponds to the X axis direction. In each of the figures described below, those features of configuration that are the same as those described in FIG. 1 are denoted by the same reference numerals.

The lithography apparatus 1 includes charged particle beam source 2, an optical system 5 configured to divide, deflect and focus the charged particle beam 4 that is dispersed by the cross over 3 into a plurality of charged particle beams, a substrate stage 7 configured to hold a substrate 6, and a control unit 8 configured to control the operation or the like of the respective constituent elements of the lithography apparatus 1. As used herein, since the charged particle beam 4 is immediately attenuated in an atmosphere of air, or in order to prevent electrical discharge due to high voltage, the respective constituent elements such as the charged particle beam source 2 or the optical system 5 or the like are disposed in an inner portion of a vacuum device (not illustrated) that is subjected to internal pressure adjustment by a vacuum discharge system. The substrate 6 that is the processed body is, for example, a wafer configured from monocrystalline silicon, and has a photosensitive resist coated onto a surface thereof.

The charged particle beam source 2 is a mechanism configured to emit the charged particle beam 4 by application of heat or an electrical field. When the charged particle beam source 2 is assumed to emit the charged particle beam 4 as an electron beam, a so-called thermionic electron source unit is employed as the charged particle beam source 2 that comprises, for example, LaB₆, BaO/W (dispenser cathode), or the like as an electron emission material. In the figures, the orbit of the charged particle beam 4 that is dispersed from the cross over 3 is illustrated by the broken line.

The optical system 3 is a projection system that projects the charged particle beam 4 emitted from the charged particle bears source 2 onto the substrate 6. In order from the side near to the charged particle beam, source 2, the optical system 5 includes a collimeter lens 10, an aperture array 11, a condenser lens array 12, and a plurality of sub-arrays 13. Furthermore, the optical system 5 includes a blanking deflector array (first deflector array) 14, a second deflector array 15, a blanking aperture 16, a third deflector array 17, and an objective lens array 18. Firstly, the collimeter lens 10 is an electromagnetic lens or electrostatic lens that focuses (configures in parallel) the charged particle beam 1 dispersed by the cross over 3 to thereby form a surface area beam of a desired dimension.

The aperture array 11 is an opening member that includes a plurality of openings 11a arrayed as a matrix, and is configured to divide the charged particle beams 4 that are substantially incident in a perpendicular configuration from the collimeter lens 10 into a plurality of beams. FIG. 1 is a schematic view of the planar shape of the aperture array 11 seen from the side of incidence of the charged particle beams. When m and n are defined as a natural number, the rows in the aperture array 11 that includes n-number of openings arranged equidistantly with a second interval along the second direction includes a plurality of openings 11a arranged in m rows equidistantly in a first interval along the first direction. The openings at the head of each row are disposed in the second direction at a deviation configured, as a third interval that is smaller than the first interval, more specifically, at l/m. the interval of the first interval. Furthermore, in addition to a first opening group that includes a (m×n) openings 11a₁, the plurality of openings 11a includes a second opening group that includes openings 11a₂ (below referred to as “spare openings” disposed in an (m×n) array according to a specified plan. The second opening group is preferably positioned within a range in the second direction that includes the first opening group, and at a position that differs from the first opening group in the first direction. The parallel configuration of the first opening group and the second opening group into a single aperture array enables reduction of the irradiation range of the charged particle beams 4, and therefore is useful in relation to irradiation efficiency. In particular, the aperture array 11 according to the present embodiment disposes n-number of redundant opening columns in a single row relative to the first opening group (collection of openings 11a₁) that is arrayed as an (m×n), as the second opening group (collection of the spare openings 11a₂). The position of the spare openings 11a₂ relative to the first direction coincides to the opening position of the row of openings 11a₁ that is provided at the most distant position from the spare openings 11a₂ in the second direction. Furthermore, the position of the spare openings in the second direction is separated by a fourth interval (same as the first interval in the present embodiment) from the row that is most proximate to the position in the first direction. The aperture array 11 enables production of the charged particle beam (second charged particle beam group) 4 due to the spare openings 11a₂ in addition to the (m×n) charged, particle beams (first charged particle beam group) 4 by having the plurality of openings 11a.

The condenser lens array 12 disposes a condenser lens configured from three electrode plates (in the figure the three electrode plates are illustrated as a single unit) that include circular holes, and are configured to enable incidence of the respective charged particle beams 4 into the openings that are arrayed in the sub-array 13. FIG. 1 illustrates a schematic view of the planar shape of the sub-array 13 seen from the side of incidence of the charged particle beam and corresponding to the planar shape (disposition of the opening 11a) of the aperture array 11 shown in the upper portion. The sub-array 13 includes at least one opening 13a, and forms sub-beams 4s in which the respectively incident charged particle beams are divided into a further plurality. In the example illustrated in FIG. 1, the shape of the respective openings 11a , 13a disposed in the aperture array 11 and the sub-array 13 is rectangular but may be configured in an arbitrary shape. The blanking deflector array (shielding portion) 14 includes a plurality of blanking deflectors (electrostatic blankers) disposed in a matrix shape to thereby enable individual shielding of the sub-beams 4s. The respective blanking deflectors select sub-beams 4s arriving at the substrate 6 by whether or not the corresponding sub-beam 4s is deflected, that is to say, by whether a target sub-beam 4s is shielded or not by the blanking aperture 16 that is disposed downstream. The second deflector array (deflector array) 15 can individually move the sub-beams 4s that have passed through the respective openings 11a, 13a of the aperture array 11 and the sub-array 13 in the second direction within the surface of the substrate 6. The third deflector array (scanning deflector array) 17 can individually deflect the sub-beams 4s that have passed through the respective openings 11a, 13a of the aperture array 11 and the sub-array 13 in the first direction or the second direction in synchronization with the movement of the substrate stage 7 in the first direction. Furthermore, the objective lens array 18 focuses the sub-beams 4s that have passed through the third deflector array 17 onto the substrate 6. FIG. 1 illustrates an example in which the second deflector array 15 is disposed in front of the upstream side of the blanking aperture 16, and the third deflector array 17 is disposed in front of the upstream side of the objective lens array 18, however, modification as required is possible.

The substrate stage 7 is a holding unit that holds the substrate 6 with, for example, electrostatic adhesion, and that can move in at least the first and the second directions. The movement position of the substrate stage 7 is measured in real time by a laser interferometer (measuring device) or the like (not illustrated).

The control unit 8 includes a main control system 20, a blanking control circuit 21, a second deflector control circuit 22, a third deflector control circuit 23, and a stage control circuit 24. The main control system 20 is configured by, for example, a computer or the like, and is connected to the respective constituent elements(the respective control circuits) of the lithography apparatus 1 through a line, and enables overall control of the respective constituent elements by use of a program or the like. In particular, the control unit 8 according to the present embodiment controls at least the blanking control circuit 21, the second deflector control circuit 22, the third deflector control circuit 23, and the stage control circuit 24. The blanking control circuit 21 performs separate control of the plurality of blanking deflectors contained, in the blanking deflector array 14. The second deflector control circuit 22 performs separate control of the plurality of deflectors contained in the second deflector array 15. The third deflector control circuit 23 performs separate control of the plurality of deflectors contained in the third deflector array 17. The stage control circuit 24 controls the positioning of the substrate stage 7 with reference to the positional measurement from the laser interferometer.

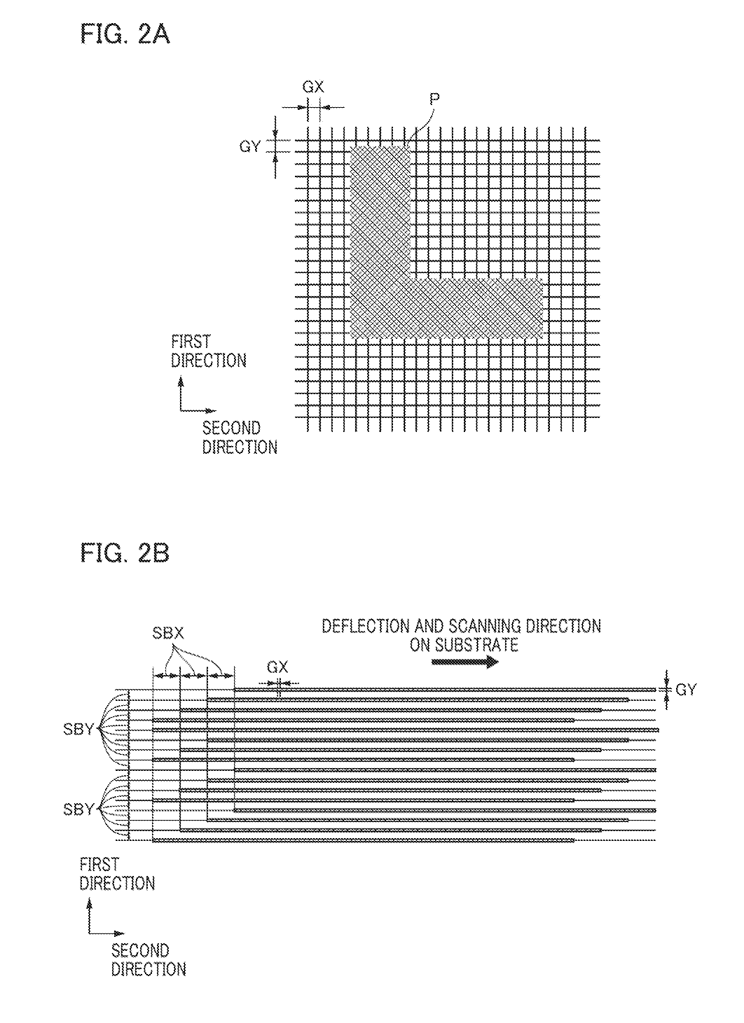

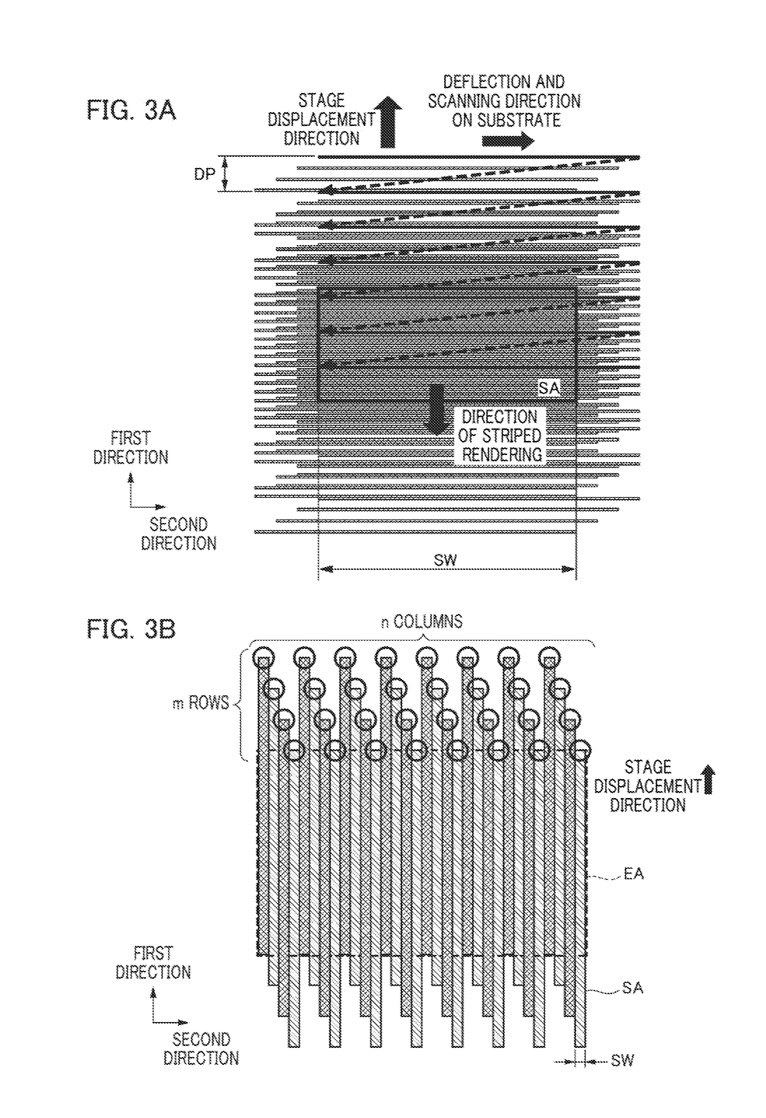

Next, the writing operation of the lithography apparatus 1 will be described. Firstly, FIG. 2A and 2B, and FIG. 3A and 3B illustrate the basic operation during writing by the lithography apparatus 1. FIG. 2A and 28, and FIG. 3A and 3B illustrate an example in which the aperture array 11 comprises openings 11a in 4 rows and 8 columns, and a single sub-array 13 forms openings 13a in 4 rows and 4 columns. In order to describe the basic operation, the aperture array 11 includes only the first opening group (openings 11a₁) described above, whereas, the second opening group (spare openings 11a₂) will not be considered.

FIG. 2A is a schematic plan view illustrating the respective sub-beams 4s allocated to the writing pattern set on the substrate 6. The respective sub-beams 4s are allocated with ON at each grid point corresponding to the writing pattern P (the pitch (grid pitch) in the first and second directions respective being GY and GX). The first direction and the second direction as described above are mutually orthogonal on the surface of the substrate 6, and the first direction is the direction in which the substrate 6 is moved by the substrate stage 7. In addition, the first direction and the second direction is the direction in which projection can be executed so that the position of the 4-row 4-column openings 13a on the sub-array 13 are configured equidistantly, and the direction that is orthogonal thereto. When executing measurement of the position of the substrate stage 7 by use of the laser interferometer, the optical axis of the laser interferometer preferably coincides substantially with the first direction and the second direction.

FIG. 2B is a schematic plan view illustrating an image (locus) to be drawn by the sub-beam group(collection of sub-beams 4s oriented towards the substrate 6) from one sub-array 13 on the substrate 6 by a single execution of deflection and scanning by the third deflector array 17. Each sub-beam 4s in the sub-beam group focuses a pitch in the first direction and the second direction (sub-beam pitch) respectively as SBY and SBX on the substrate 6. Furthermore, the dimension in the first direction of a single focused image (width) coincides with the grid pitch GY. During writing, the substrate stage 7 moves in a first direction, and the third deflector array 17 deflects and scans the respective sub-beams 4s in the second direction to write the image along the second direction. Furthermore, the blanking of the respective sub-beams 4 is controlled by the blanking deflector array 14 in relation to each grid point that is regulated by the grid pitch GX.

FIG. 3A is a schematic plan view illustrating an image to be drawn on the substrate 6 by the sub-beam group from the single sub-array 13 by a plurality of deflection and scanning operations. The striped region SA is written, on the substrate 6 by continuous repetition of the operation illustrated in FIG. 2B by the substrate stage 7 and the third deflector array 17, More specifically, the substrate stage 7 moves continuously in the first direction, on the other hand, the third deflector array 1 sequentially repeats deflection and scanning of each sub-beam 4s in the second direction through flyback in the deflection width of the first direction, as shown by the arrows in the broken line. This operation enables writing on the substrate 6 of the striped region SA having a width SW that is filled with the image of each sub-beam 4s as illustrated by the solid-line frame in a direction that is opposite to the stage movement direction along the first direction. The formation conditions for the striped region SA satisfy below Formulae (1) to (3) when K, L, M are natural numbers and the number of sub-beams 4s from the single sub-array 13 is defined as N².

N²=K×L+1 (1)

SBY=GY×K (2)

D P=(K×L+1)×GY=N²×GY (3)

The sub-beam pitch SBY in the first direction is determined by application of the value K that satisfies Formula (1) into Formula (2) to thereby realize miniaturization of the grid pitch GY in the absence of miniaturization of the interval in each blanking deflector or the opening of the aperture array 11 that represents the limit on the manufacturing surface. The lithography apparatus 1 to write more miniaturized pattern with this miniaturization of the grid pitch GY. Furthermore, the determination of the deflection width DP in the second direction from Formula (3) enables writing in any portion of the striped region SA in the grip pitch GY, In the example in FIG. 3A, K=5, L=3, and N=4.

FIG. 3B is a schematic plan view illustrating an image to be drawn on the substrate 6 by the plurality of charged particle beams generated by the aperture array 11, in particular, the positional relationship to the respective striped regions SA is described. When writing is executed using (m×n) charged particle beams 4, the lithography apparatus 1 configures the respective striped regions SA that are drawn by the m-number charged particle beams 4 that have mutually different leading positions in the first direction as a single cycle, and simultaneously brings written images from n-number of cycles into proximity. In FIG, 3B, the circles are added to the head position of each striped region SA, and in particular, the white circles indicates a state in which the charged particle beam 4 is irradiated onto the substrate 6 . In this manner, a writing region EA is written by filling the (m×n) striped regions SA on the substrate 6 without leaving a gap. In the example in FIG. 3B, m=4 and n=8.

In general, in a multibeam lithography apparatus, when there is a charged particle beam that does not satisfy the use conditions (hereinafter referred to as a “defective beam”), there is the possibility that a desired striped region SA will not be written on the substrate. For example, a defective beam is a charged particle beam that does not satisfy desired characteristics or a charged particle beam that cannot be individually blanked. “Use conditions” as used herein ate the conditions required for writing of a desired pattern on a substrate in relation to the timing of the blanking, the arrival position of the charged particle beam on the substrate, the current value of the charged particle beam (sub-beam), or the shape of the charged particle beam (sub-beam). Furthermore, in addition to a defective beam, a charged particle beam that does not satisfy conditions enabling deflection by the second deflector array 15 (hereinafter referred to as a “deflecteion-defective beam”) may be present. “Conditions enabling deflection” as used herein are conditions enabling deflection by a desired amount in the second direction, or a charged particle beam deflected in the second direction that satisfies a use condition. The situation in which a deflecteion-defective beam is present will be described below.

In order to avoid production, of an unintended striped region due to the presence of a defective beam as described above, the lithography apparatus 1 executes writing correction as described in the examples below when a defective beam is present. In the following description, a determination of whether or not a defective bears is present, that is to say, whether or not the respective charged particle beams satisfy the above use conditions, or whether or not a compensating beam or substitute beam can be deflected in the second direction as described below, or the like is determined in advance by the control unit 8 prior to execution of the writing correction.

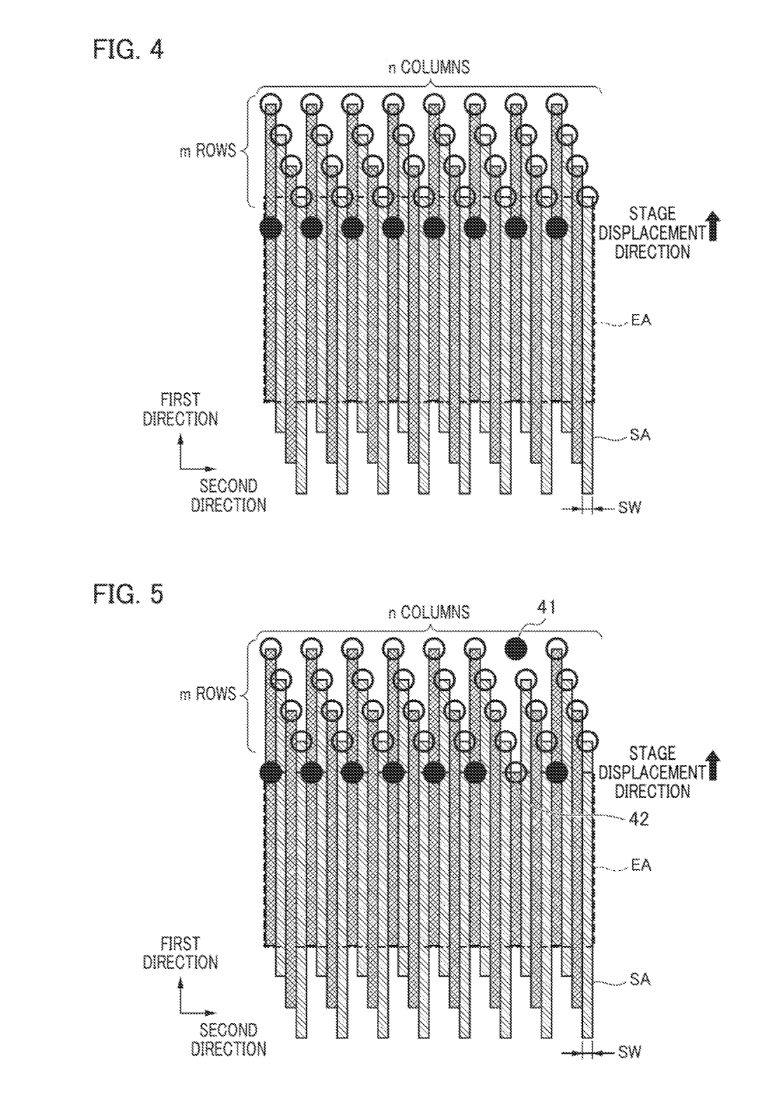

Firstly, prior to the description of each example of the writing control below, the writing configuration will be described with reference to a configuration in which all of the charged particle beams 4 divided by the aperture array 11 operate normally. FIG. 4 is a schematic plan view illustrating the writing configuration on the substrate 6 under these circumstances, and more specifically, when the first charged particle beam group including the (m×n) charged particle beam 4 does not include a defective beam, and a deflecteion-defective beam that does not satisfy conditions enabling deflection. Under these circumstances, since all the charged particle beams 4 enable formation of a desired writing region EA without production of a stripe blank, the charged particle beams 4 formed by the spare openings 11a₂ are shielded with respect to the substrate 6 by the second deflection array 15. In the figures illustrated in FIG. 4 to FIG. 11, the circles represent the head position of each striped region SA that is written by the charged particle beams 4 that pass through the plurality of openings 11a (including the spare openings 11a₂ ) that are disposed respectively in the aperture arrays 11. In particular, the white circles that are shown in those circles indicate a configuration in which the charged particle beam 4 is normally irradiated onto the substrate 6. In contrast, the black circles indicate a configuration in which although the charged particle beam 4 can be irradiated onto the substrate 6, intentional shielding results in no irradiation at that time, or a configuration in which irradiation is not normal. Furthermore, a basic operation such as the stage movement direction in the writing configuration illustrated in the figures in FIG. 4 to FIG. 11 is assumed to be the same as the operation illustrated in the figures in FIG. 2A and 2B, and FIG. 3A and 3B.

Next, a first example of writing control in the lithography apparatus 1 will be described. FIG. 5 is a schematic plan view illustrating a first example of the configuration during writing correction when a defective beam 41 is present in the first charged particle beam group that corresponds to FIG. 4. in particular, the position in the present example of the openings 11a₁ corresponding to the defective beams 41 coincide in the second direction with an opening of the plurality of spare openings 11a₂. When a defective beam 41 is present, the lithography apparatus 1 cannot write a normal striped region SA, and as a result, cannot form a normal writing region EA on the substrate 6. Therefore, in the circumstances of the first example, the control unit 8 firstly causes the blanking deflector array 14 to shield the defective beams 41 through the blanking control circuit 21. Then, the control unit 8 releases the shielding state of the spare openings 11a₂ that are positioned corresponding to the first direction of the defective beams 41 through a blanking control circuit 21. Therefore, in substitution for the defective beams 41, the control unit 8 causes the charged particle beams (hereinafter referred to as “compensating beams”) from the preparatory holes 11a₂ to reach the substrate 6 and thereby compensating the writing that was to be performed by the defective beams 41. At this time, the control unit 8 causes writing by the compensating beams 42 by using writing data originally intended for writing by the defective beams 41 and by only causing a deviation in the writing timing {(position in first direction of defective beams 41—position in first direction of compensating beam 42)/stage moving velocity}. In this manner, a writing region EA is written by filling in the (m×n) striped regions SA on the substrate 6 without leaving a gap. That is to say, the control unit 8 does not have to execute deflection by use of the second deflector array 15 if the position of the defective beams 41 in the second direction coincides with any of the positions in the second direction of the spare openings 11a. The control unit 3 causes production of the compensating beams 42 by merely causing a deviation in the writing timing to thereby write the striped region SA that was to be written by the defective beams 41.

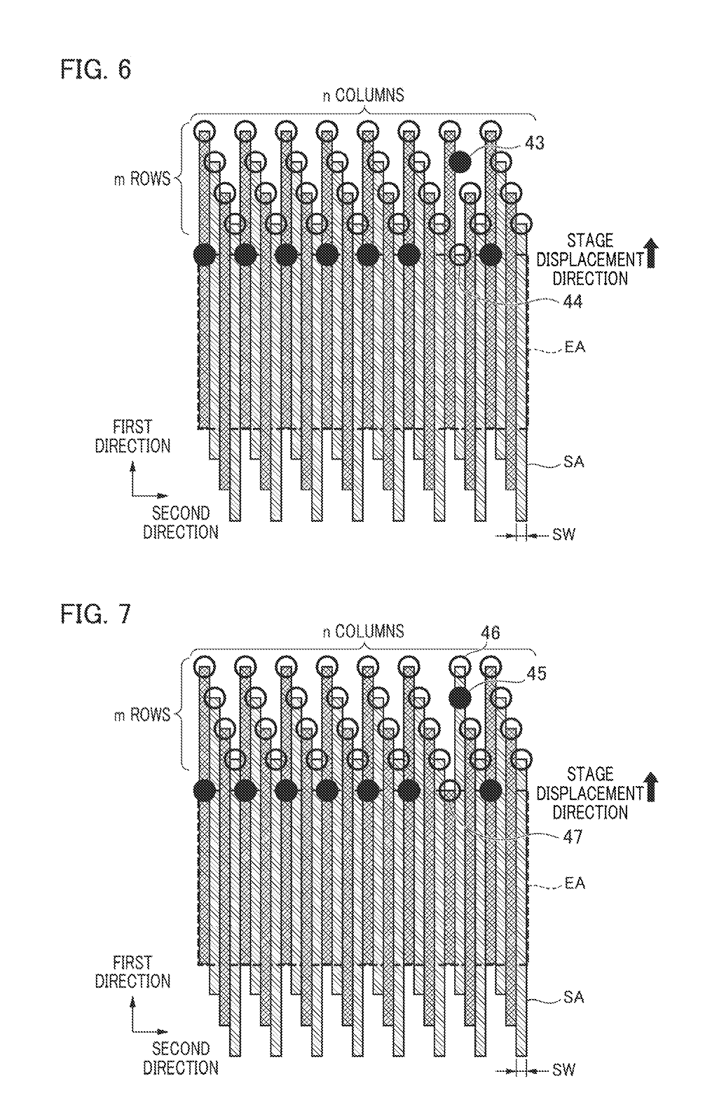

A second example of writing control by the lithography apparatus 1 will be described below. FIG. 6 is a schematic plan view illustrating a configuration during writing compensation when a defective beam 43 is present in the first charged particle beam group according to a second example. In particular, in the present example, the position of the opening 11a₁ corresponding to the defective beams 43 differs from that in the first example, and does not coincide in the second direction with the position of any of the openings of the plurality of spare openings 11a. In this configuration, the control unit 8 uses the second deflector array 15 to cause a deflection in the second direction of the compensating beams 14 that perform writing in substitution for the defective beams 43 to thereby coincide with the position of the defective beams 43 in the second direction, and thereby reach the substrate 6. The control unit 8 firstly causes the blanking deflector array 14 to shield the defective beams 43 through the blanking control circuit 21. Then, the control unit 8 uses the blanking control circuit 21 to release the shielding state of the spare openings 11a that are positions in proximity to the defective beams 43 in the second direction. The control unit 3 uses the second deflector array 15 through the second deflector control circuit 22 to cause a deflection of the compensating beams 44 from the spare openings 11a₂ to thereby coincide with the position of the defective beams 43 in the second direction, and thereby reach the substrate 6. At this time, the control unit 8 causes writing by the compensating beams 44 by using writing data originally intended for writing by the defective beams 43 and by only causing a deviation in the writing timing {(position in first direction of defective beams 43—position in first direction of compensating beams 44)/stage moving velocity}. In this manner, a writing region SA is written by filling in the (m×n) striped regions SA on the substrate 6 without leaving a gap. When the control unit 8 selects an opening from the plurality of spare openings 11a₂ for irradiation of the compensating beams 44, the opening that is in proximity to the defective beams 43 in the first direction, and preferably, in the most proximate position is selected. This is due to the fact that change in the focusing performance resulting from deflection of the charged particle beams (compensating beams 44) can be further reduced by minimising the deflection amount by the second deflector array 15. In the present example, the deflection amount by the second deflector array 15 may be merely a single width SW of the striped region SA.

A third example of writing control by the lithography apparatus 1 will be described below. FIG. 7 corresponds to FIG. 4, and is a schematic plan view illustrating a configuration during writing compensation when a defective beam 45 is present in the first charged particle beam group according to a third example. In the present example, the position of the opening 11a₁ corresponding to the defective beams 45 in the same manner as the second example does not coincide in the second direction with the position of any of the openings of the plurality of spare openings 11a₂. However, the control unit 8 executes writing control that is different from the second example to thereby write the writing region SA. In this configuration, the control unit 8 adopts a normally operating charged particle beam (hereinafter referred to as “substitute beam”) from the plurality of openings 11a₁ as a charged particle beam to compensate writing in substitution for the defective beam 45. Furthermore, in relation to the use of the substitute beam 46 in writing in substitution for the defective beam 45, the control unit 8 causes writing of the striped region SA, that was to be written by the charged particle beam designated prior to the substitute beam 46, by the compensating beam 47 from any of the opening of the plurality of spare opening 11a₂₁. The control unit 8 firstly causes the blanking deflector array 14 to shield the defective beams 45 through the blanking control circuit 21. Then, the control unit 8 uses the second deflector control circuit 22 so that the second deflector array 15 deflects the substitute beams 46 from the opening 11a₁ to coincide with the defective beam 4 and the second direction, and thereby reach the substrate 6. On the other hand, simultaneously to the deflection of the substitute beams 46, the control unit 8 uses the blanking control circuit 21 to release the shielding state of the spare openings 11a₂ that are positions corresponding to the second direction of the charged particle beam designated prior to the substitute beam 46, to thereby cause the compensating beams 4 to reach the substrate 6. At this time, the control unit 8 causes writing by the substitute beams 46 by using writing data originally intended for writing by the defective beams 45 and by only causing a deviation in the writing timing {(position in first direction of defective beams 45—position in first direction of substitute beams 46)/stage moving velocity}. Furthermore, the control unit 8 causes writing by the compensating beams 47 by using writing data originally intended for writing by the charged particle beam designated prior to the substitute beam 46 and by only causing a deviation in the writing timing {(position in first direction of substitute beam 46—position in first direction of compensating beams 47)/stage moving velocity}. In this manner, a writing region EA is written by filling in the (m×n) striped regions SA on the substrate 6 without leaving a gap. When the control unit 8 selects an opening from, the plurality of spare openings 11a₂ for irradiation of the substitute beams 46, the opening such that the charged particle beam designated prior to the substitute beam 46 is in proximity to the second direction of the defective beams 45, and preferably, in the most proximate position is selected. Furthermore, the control unit 8 selects the opening for irradiation of the compensating beams 47 from the plurality of the spare openings 11a₂, and selects the opening in a position corresponding to the second direction of the defective beams 45. This selection enables the deflection amount of the charged particle beam used in compensating of the writing by the defective beam 45 to be minimized in the same manner as the second example.

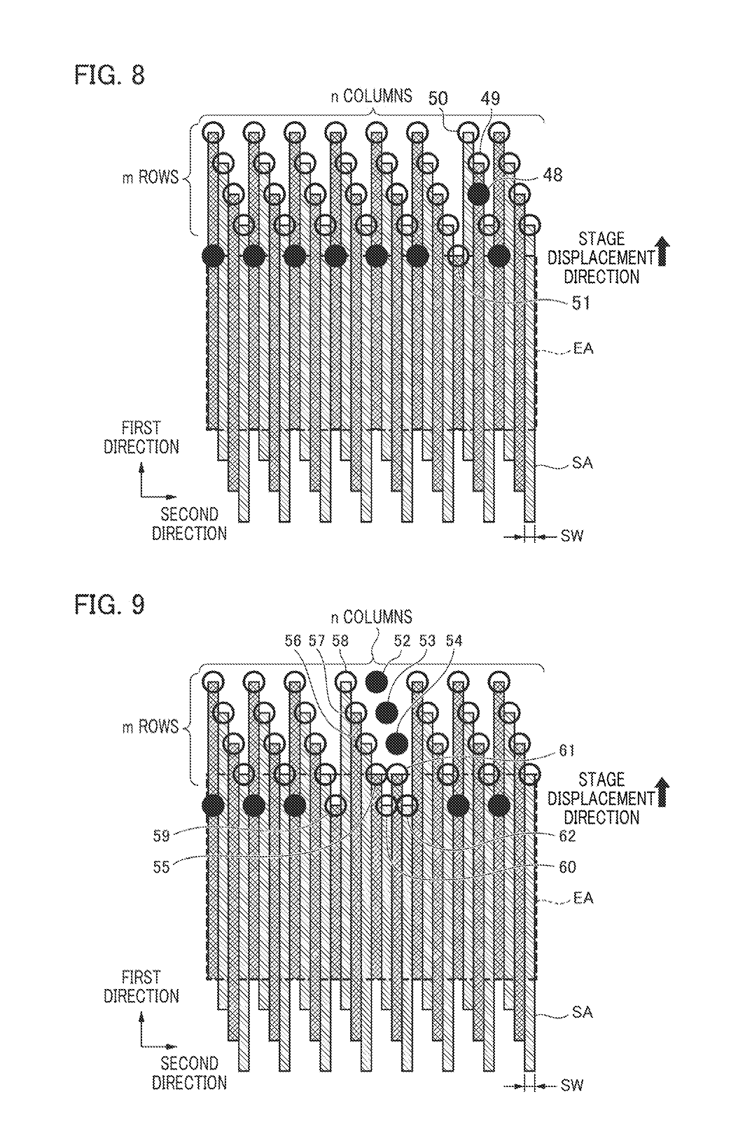

A fourth example of writing control by the lithography apparatus 1 will be described below. FIG. 8 corresponds to FIG. 4, and is a schematic plan view illustrating a configuration during writing compensation when a defective beam 48 is present in the first, charged particle beam group according to a fourth example. In particular, the positions in the present example of the openings 11a₁ corresponding to the defective beams 48 are separated by a distance corresponding to twice the width SW from the position of any of two spare openings 11a₂ that are adjacent in the second direction. As described above, the deflection amount of the charged particle beam used in compensating in the writing by the defective beam 48 is preferably minimised. In this regard, as described in the fourth example above, firstly the control unit 8 adopts a substitute beam 49 in which the charged particle beam prior to deflection is in proximity to the defective beam 48 as the charged particle beam to execute compensation of writing in substitution for the defective beam 48. In relation, to the use of the substitute beam 49 in writing in substitution for the defective beam 48, compensation of writing with any of the charged particle beams is required also for the striped region SA that was to be written by the charged particle beam designated prior to the substitute beam 49. In this regard, the control unit 8 causes writing of the striped region SA that was to be written by the charged particle beam designated prior to the substitute beam 49 by the substitute beam 50 by deflecting the charged particle beam that was in proximity to the charged particle beam designated prior to the substitute beam 49. Next, the control unit 8 uses the blanking control circuit 21 to release the shielding state of the spare openings 11a₂ that are in positions corresponding to the second direction of the charged particle beam designated prior to the substitute beam 50, to thereby cause the compensating beams 51 to reach the substrate 6. At this time, the control unit 8 causes writing by the substitute beams 49 by using writing data originally intended for writing by the defective beams 48 and by only causing a deviation in the writing timing {(position in first direction of defective beams 48—position in first direction of substitute beams 49)/stage moving velocity}. Furthermore, the control unit 8 causes writing by the compensating beams 50 by using writing data originally intended for writing by the charged particle beam designated prior to the substitute beam 49 and by only causing a deviation in the writing timing {(position in first direction of substitute beams 49—position in first direction of substitute beams 50)/stage moving velocity}. In addition, the control unit 3 causes writing by the compensating beams 51 by using writing data originally intended for writing by the charged particle beam designated prior to the substitute beams 50 and by only causing a deviation in the writing timing {(position in first direction of substitute beams 50—position in first direction of compensating beam 51)/stage moving velocity}. In this manner, a writing region FA is written by filling in the (m×n) striped regions SA on the substrate 6 without leaving a gap. Therefore, a charged particle beam that is adjacent to the defective beam is used as a first substitute beam for compensating the writing in substitution for the defective beam, and a charged particle beam that is adjacent to the first substitute beam is used, as a second substitute beam for compensating the writing in substitution for the first substitute beam to thereby minimize the respective deflection amounts. That is to say, the same compensation effect is enabled without reference to the position of the defective bears by executing at least one repetition of substitute writing of the striped region SA that was to be originally written by the adjacent charged particle beam from the charged particle beams emitted from the plurality of openings 11a₁. In particular, in the present configuration, the number of deflected charged particle beams can be reduced by preferential application of a compensating beam that is in proximity to the position in the second direction of the defective beams. A reduction in the number of deflected charged particle beams enables a reduction in advance of the number of charged particle beams whose focusing performance will foe varied by deflection. Furthermore, it is possible to reduce in advance the number of charged particle beams for which the writing timing must be deviated.

A fifth example of writing control by the lithography apparatus 1 will foe described below. FIG. 9 corresponds to FIG. 4, and is a schematic plan view illustrating a configuration during writing compensation when respective defective beams 52, 53, 54 that are adjacent in the second direction are present in the first charged particle beam group according to a fifth example. In this example, a writing region EA can be written by filling without leaving a gap in the (m×n) striped regions SA on the substrate 6 by application of the substitute writing using the adjacent charged particle beams described in the fourth example. The correspondence relationship of the substitute beams and the compensating beams corresponding to the defective beams 52, 53, 54 in the present example will be described. Firstly, writing in substitution for the first defective beam 52 is performed by the first substitute beam 55 in which the adjacent first charged particle beam is deflected on the left side of the figure in the second direction of the first defective beam 52. At the same time, writing in substitution for the first charged particle beam is performed by the second substitute beam 56 in which the adjacent second charged particle beam is deflected on the left side of the figure in the second direction of the first charged particle beam. Furthermore, writing in substitution for the second substitute beam 56 is performed by the third substitute beam 57 in which the adjacent third charged particle beam is deflected on the left side of the figure in the second direction of the second charged particle beam. Furthermore, writing in substitution for the fourth substitute beam 58 is performed by the first compensating beam 59 at a position corresponding in the second direction, of the fourth charged particle beam. Then writing in substitution for the second defective beam 53 is performed by the second compensating beam 60 in which the fifth charged particle beam that has passes through the adjacent spare opening 11a₂ is deflected on the left side of the figure in the second direction of the second charged particle beam. Writing in substitution for the third defective beam 54 is performed by the fifth substitute beam 61 in which the adjacent fifth charged particle bears is deflected on the left side of the figure in the second direction of the third defective beam 54. In this manner, writing in substitution for the fifth charged particle beam is performed by the third compensating beam 62 in which the sixth charged particle beam that has passed through the adjacent spare opening 11a₂ is deflected on the left side of the figure in the second direction of the fifth charged particle beam. In this context, the deviation of the respective writing timing in the present example is the same as the examples above. According to the above writing control, even when a plurality of defective beams is present, the deflection amount in the second direction of each compensating beam and substitute beam can be minimised.

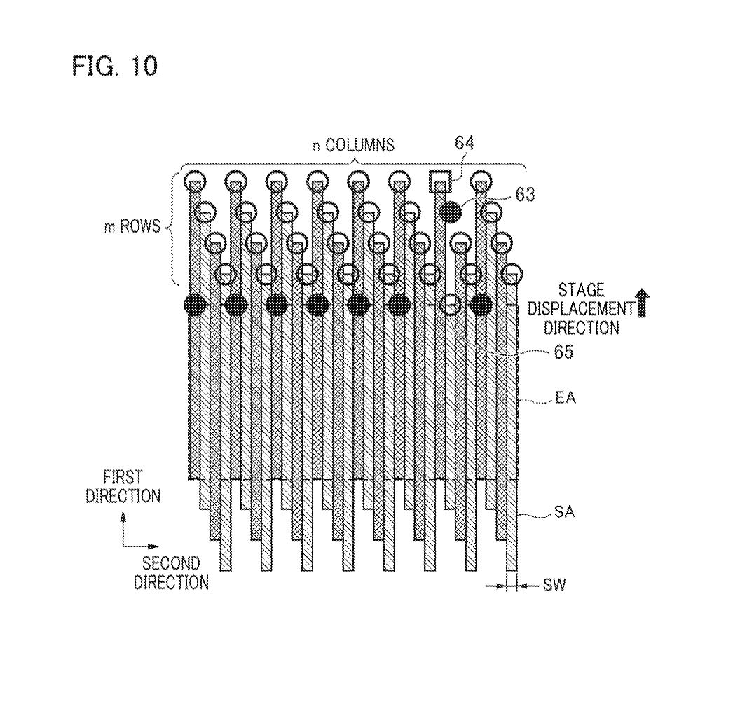

Next, a sixth example of writing control by the lithography apparatus 1 will be described below. FIG. 10 corresponds to FIG. 4, and is a Schematic plan view illustrating a configuration during writing compensation when a deflecteion-defective beam 64 in addition to a defective beam 63 is present in the first charged particle beam group according to a sixth example. The defective beam 63 is preferably shielded in advance in relation to the substrate 6 as described above to thereby prevent writing of an abnormal striped region SA. In contrast, a deflecteion-defective beam 64 described, by the square in the figure may execute writing at that position without deflection in order to satisfy the use conditions described above when deflection is not required. In the present example, since a defective beam 63 is present, writing is performed by the compensating bears 65 in relation to that defective beam 63 in the same manner as the above example. At this time, when selecting the charged particle beam to perform writing of the defective beam 63, the control unit 8 must exclude the deflecteion-defective beam 64 from the candidates. When assuming a combination of the present example with the sixth example, this is the same as the configuration of selecting the designated charged particle beam prior to the substitute beam.

In this manner, the lithography apparatus 1 compensates the writing operation by use of the compensating beam based on the relative position in the first direction of the compensating beams and the charged particle beams to be compensated by the compensating beam, when a defective beam is present in the first charged particle beam group. Therefore, the lithography apparatus 1 substantially suppresses an effect on the throughput by enabling execution of writing compensation in substitution for the defective beams in combination with the writing under a normal configuration. Note, the position of the defective beam as exemplified by each of the examples above is arbitrary, and even when a defective beam is produced in any of the (m×n) first opening group, a combination with each of the above examples is possible.

As described above, according to the embodiments of the present disclosure, a lithography apparatus can be provided that is useful in relation to throughput by compensating for an abnormal charged particle beam.

### Second Embodiment

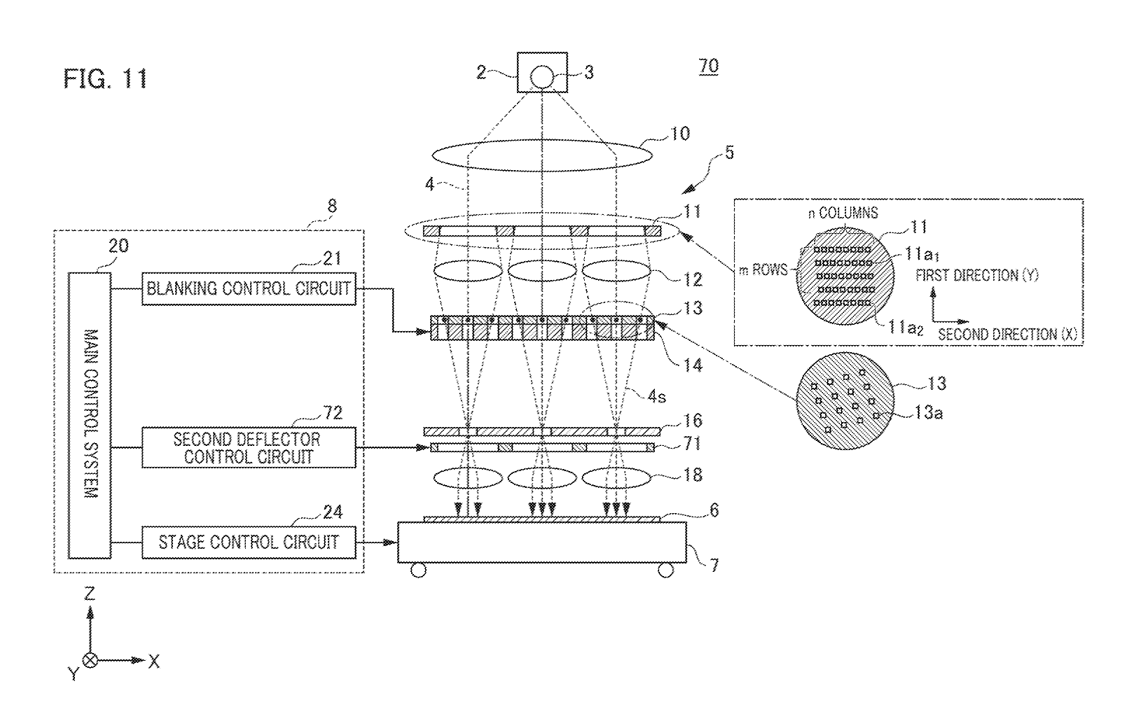

Next, a lithography apparatus according to the second embodiment of the present disclosure will be described, FIG. 11 is a schematic plan view illustrating a configuration of a lithography apparatus 70 according to the present embodiment. FIG. 11 denotes the same elements of configuration as the lithography apparatus 1 according to the first embodiment with the same reference numerals, and the description will not be repeated. The characteristic feature of the lithography apparatus 70 resides in the point that while the optical system 5 includes a deflector array corresponding to the second deflector array 15 that is present in the lithography apparatus 1 according to the first embodiment, the third deflector array 17 has been omitted. In the lithography apparatus 70, the operation of deflecting and scanning of each sub-beam 4s in the first direction and the second direction in order to draw the figure along the second direction, that is originally executed by the third deflector array 17 in the lithography apparatus 1, is performed by a second deflector array 71. The second deflector array 71 includes the operation of the third deflector array 17 described in the first embodiment, and as a result, the second deflector control circuit 72 includes the third deflector control circuit 23 described in the first embodiment. In this manner, even when the configuration of the lithography apparatus 70 is varied as described, above, the same effect as the first embodiment is obtained. In FIG. 11, the second deflector array 71 is disposed downstream of the blanking aperture 16 and upstream of the objective lens array 18. However, this is merely exemplary, and suitable modification is possible.

### (Method of Manufacturing Product)

The method of manufacturing a product according to the present embodiment of the present disclosure for example is suitably applied to the manufacture of a product such as an element that has a miniature structure or a micro-device such as a semiconductor device or the like. The manufacturing method includes a step of forming an electrostatic latent pattern using the lithography apparatus above on a photosensitive agent of a substrate coated with the photosensitive agent (step of writing on substrate), and a step of developing the substrate on which the electrostatic latent pattern is formed in the previous step. In addition, the manufacturing method may include other known steps (such as oxidizing, film deposition, vapor deposition, doping, flattening, etching, resist removal, dicing, bonding, packaging). The method of manufacturing a product according to the present embodiment is useful in comparison to a conventional method in relation to at least one of product performance, quality, productivity or production costs.

While the embodiments of the present disclosure have been described with reference to embodiment, it is to be understood that the disclosure is not limited to the disclosed embodiment. The scope of the following claims is to be accorded the broadest interpretation so as to encompass all such modifications and equivalent structures and functions.

This application claims the benefit of Japanese Patent Application No. 2012-142848 filed Jun. 26, 2012 which is hereby incorporated by reference herein in its entirety.

What is claimed is:

1. A lithography apparatus that performs writing with a charged particle beam on a substrate scanned in a first direction, the apparatus comprising:
a shielding device configured to individually shield a plurality of charged particle beams included in a first charged particle beam group and a second charged particle beam group,
a holder configured to hold the substrate and to be movable in the first direction, and
a controller,
wherein the controller is configured, if a defective beam that does not satisfy a condition exists in the first charged particle beam group, to cause the shielding device to shield the defective beam and to transmit a compensating beam, of the second charged particle beam group, for compensating for the defective beam, and to control writing with the compensating beam based on relative positions, in the first direction, between the compensating beam and a charged particle beam to be compensated for by the compensating beam.

2. The lithography apparatus according to claim 1, further comprising:
a deflector array configured to move the plurality of charged particle beams individually in a second direction orthogonal to the first direction on the substrate,
wherein the controller is configured to control the deflector array so that the compensating beam is positioned at the position, in the second direction, of the charged particle beam to be compensated for by the compensating beam.

3. The lithography apparatus according to claim 1, wherein the first charged particle beam group includes a plurality of rows, each of which includes charged particle beams disposed at a second interval along the second direction, disposed at a first interval along the first direction, head charged particle beams of the plurality of rows being arrayed, in sequence, with a deviation of a third interval, smaller than the second interval, in the second direction, and
wherein the second charged particle beam group is arrayed adjacent to the first charged particle beam group in the first direction.

4. The lithography apparatus according to claim 3, wherein the second charged particle beam group includes charged particle beams disposed at a fourth interval along the second direction.

5. The lithography apparatus according to claim 2, wherein the first charged particle beam group includes a plurality of rows, each, of which includes charged particle beams disposed at a second interval along the second direction, disposed at a first interval along the first direction, head charged, particle beams of the plurality of rows being arrayed, in sequence, with a deviation of a third interval, smaller than the second interval, in the second direction, and
wherein the second charged particle beam group is arrayed adjacent to the first charged particle beam group in the first direction.

6. The lithography apparatus according to claim 5, wherein the second charged particle beam group includes charged particle beams disposed at a fourth interval along the second direction.

7. The lithography apparatus according to claim 2, wherein the controller is configured to control, the deflector array so that a substitute beam of the first charged particle beam group is positioned at a position of the defective beam in the second direction, to control writing with the substitute beam based on relative positions between the defective beam and the substitute beam in the first direction, to control the deflector array so that the compensating beam compensates for the substitute beam, and to control writing with the compensating beam based on relative positions between, the substitute beam and the compensating beam in the first direction.

8. The lithography apparatus according to claim 7, wherein the controller is configured to control the deflector array so that the substitute hears as a first substitute beam is substituted by a second substitute beam of the first charged particle beam group, and to control writing with the second substitute beam based on relative positions between the first substitute beam and the second substitute bears in the first direction.

9. The lithography apparatus according to claim 1, wherein the controller is configured to select a charged particle beam to be the compensating beam or the substitute beam based on relative positions between the defective beam and the compensating beam or the substitute beam in the second direction.

10. The lithography apparatus according to claim 1, wherein the controller is configured to control writing with the compensating beam or the substitute beam based on a moving velocity of the holder in the first direction.

11. The lithography apparatus according to claim 1, further comprising a scanning deflector configured to scan a plurality of charged particle beams, incident on the substrate, along the second direction in synchronization with a movement of the holder in the first direction.

12. The lithography apparatus according to claim 2, wherein the deflector array is configured to scan the plurality of charged, particle beams, incident on the substrate, along the second, direction in synchronization with a movement of the holder in the first, direction.

13. The lithography apparatus according to claim 7, wherein the controller is configured to exclude a deflection-defective beam, having a defect in deflection thereof by the deflector array, from a candidate for the compensating beam or the substitute beam.

14. The lithography apparatus according to claim 1, wherein the shielding device includes a blanking deflector array configured to individually deflect and blank a plurality of charged particle beams included in the first charged particle beam group and the second charged particle beam group.

15. A method of manufacturing an article, the method comprising:
writing on a substrate using a lithography apparatus; and
developing the substrate having undergone the writing, and
processing the developed substrate to manufacture the article,
wherein the lithography apparatus performs the writing with a charged particle beam on the substrate scanned in a first direction, the apparatus including:
a shielding device configured to individually shield a plurality of charged particle beams included in a first charged particle beam group and a second charged particle beam group,
a holder configured to hold the substrate and to be movable in the first direction, and
a controller,
wherein the controller is configured, if a defective beam, that does not satisfy a condition exists in the first charged particle beam group, to cause the shielding device to shield the defective beam and to transmit a compensating beam, of the second charged particle beam group, fox compensating for the defective beam, and to control writing with the compensating beam based on relative positions, in the first direction, between the compensating beam and a charged particle beam to be compensated for by the compensating beam.
